(19) United States
(12) Patent Application Publication
(10) Pub. No.: US 2011/0285661 A1
(43) Pub. Date: Nov. 24, 2011

(54) Periphery Conductive Element for Touch Screen

(76) Inventor: Steven Porter HOTELLING, Los Gatos, CA (US)

(21) Appl. No.: 12/851,401

(22) Filed: Aug. 5, 2010

Related U.S. Application Data
(60) Provisional application No. 61/345,888, filed on May 18, 2010.

(51) Int. Cl. G06F 3/045; H03K 17/975

(52) U.S. Cl. 345/174; 200/600

(57) ABSTRACT

A touch screen is disclosed. The touch screen can include a touch panel and a display, where the display can have a conductive element coupled to or disposed along at least one side at a periphery of a conductive layer of the display. The conductive element can drive the conductive layer from multiple positions along the element to provide a grounding shield for the touch screen. The grounding shield can shunt display interference to ground rather than into the touch panel. The conductive element can also drive the conductive layer from multiple positions along the element, thereby providing an increased bandwidth, to quickly reach an appropriate voltage in association with the touch panel, consequently improving the touch sensitivity of the panel. The conductive element can include multiple configurations, e.g., a ring around a perimeter of the conductive layer, a partial ring around three sides of the periphery of the conductive layer, two elements on opposite sides at the periphery, and one element along one side at the periphery. The conductive element can be continuous or segmented.

### CROSS REFERENCE TO RELATED APPLICATIONS

This application claims benefit of U.S. Provisional Application No. 61/345,888 filed May 18, 2010, the contents of which are incorporated by reference herein in their entirety for all purposes.

### FIELD OF THE DISCLOSURE

This relates generally to touch screens and, more particularly, to a conductive element of a touch screen for improved touch sensing.

### BACKGROUND OF THE DISCLOSURE

Many types of input devices are presently available for performing operations in a computing system, such as buttons or keys, mice, trackballs, joysticks, touch sensor panels, touch screens and the like. Touch screens in particular are popular because of their ease and versatility of operation as well as their declining price. A touch screen can include a touch sensor panel, which can be a clear panel with a touch sensitive surface, and a display device such as a liquid crystal display (LCD) that can be positioned partially or fully behind the panel so that the touch sensitive surface can cover at least a portion of the viewable area of the display device. The touch screen can allow a user to perform various functions by touching the touch sensor panel using a finger, stylus or other object at a location often dictated by a user interface (UI) being displayed by the display device. In general, the touch screen can recognize a touch and the position of the touch on the touch sensor panel, and the computing system can then interpret the touch in accordance with the display appearing at the time of the touch, and thereafter can perform one or more actions based on the touch.

In some instances, the touch sensor panel can be adversely affected by the proximity of the display device, consequently affecting recognition and interpretation of a touch. Such adverse effects can be more apparent when the touch is proximate or near to the touch sensor panel, rather than directly on the panel.

### SUMMARY

This relates to a periphery conductive element in a touch screen's display to improve touch sensing in the touch screen's touch panel, in particular proximate or near touch sensing. The conductive element can be coupled to or disposed along one or more sides at a periphery of a conductive layer of the display to drive the conductive layer to provide a grounding shield and to improve touch sensitivity. The conductive layer can provide the grounding shield to limit display noise reaching the touch panel. The conductive layer can improve touch sensitivity of the touch panel by being driven quickly to an appropriate voltage associated with the touch panel. The conductive element can include multiple configurations, e.g., a ring around a perimeter of the conductive layer, a partial ring around three sides at the periphery of the conductive layer, two elements on opposite sides at the periphery, and one element along one side at the periphery. An element can be continuous or segmented.

### BRIEF DESCRIPTION OF THE DRAWINGS

FIG. 1 illustrates an exemplary touch screen according to various embodiments.

FIG. 2 illustrates an exemplary conductive layer having a conductive ring disposed thereon according to various embodiments.

FIG. 3 illustrates an exemplary conductive layer acting as a grounding shield according to various embodiments.

FIGS. 4a and 4b illustrate an exemplary conductive layer with increased bandwidth to improve touch sensitivity of an adjacent touch panel according to various embodiments.

FIGS. 5 through 10 illustrate additional exemplary conductive layers having conductive elements disposed thereon according to various embodiments.

FIG. 11 illustrates another exemplary touch screen according to various embodiments.

FIG. 12 illustrates an exemplary mobile telephone incorporating a touch screen according to various embodiments.

FIG. 13 illustrates an exemplary digital media player incorporating a touch screen according to various embodiments.

FIG. 14 illustrates an exemplary personal computer incorporating a touch screen according to various embodiments.

FIG. 15 illustrates an exemplary computing system incorporating a touch screen according to various embodiments.

### DETAILED DESCRIPTION

In the following description of various embodiments, reference is made to the accompanying drawings which form a part hereof, and in which it is shown by way of illustration specific embodiments which can be practiced. It is to be understood that other embodiments can be used and structural changes can be made without departing from the scope of the various embodiments.

This relates to a touch screen having a touch panel and a display, where the display can include a conductive element along a periphery of a conductive layer of the display. The conductive element can improve touch sensing in the touch panel, in particular proximate or near touch sensing. The conductive element can be coupled to or disposed along one or more sides at a periphery of the conductive layer to drive the conductive layer to provide a grounding shield and to improve touch sensitivity. The conductive layer can provide the grounding shield to limit display noise reaching the touch panel. The conductive layer can improve touch sensitivity of the touch panel by being driven quickly to an appropriate voltage associated with the touch panel. The conductive element can include multiple configurations, e.g., a ring around a perimeter of the conductive layer, a partial ring around three sides at the periphery of the conductive layer, two elements on opposite sides at the periphery, and one element along one side at the periphery. An element can be continuous or segmented.

Unlike conventional conductive elements that provide only a single point of electrical contact with conductive layers, the conductive element being coupled to or disposed along a periphery of the conductive layer, according to various embodiments, can be in electrical contact at multiple points along the periphery and can drive the conductive layer from the multiple points so as to quickly and effectively provide a grounding shield and increased bandwidth.

The ability to improve grounding and touch sensitivity in the touch screen with a periphery conductive element can advantageously provide more accurate and faster touch detection, as well as power savings, by not having to repeat poor touch measurements.

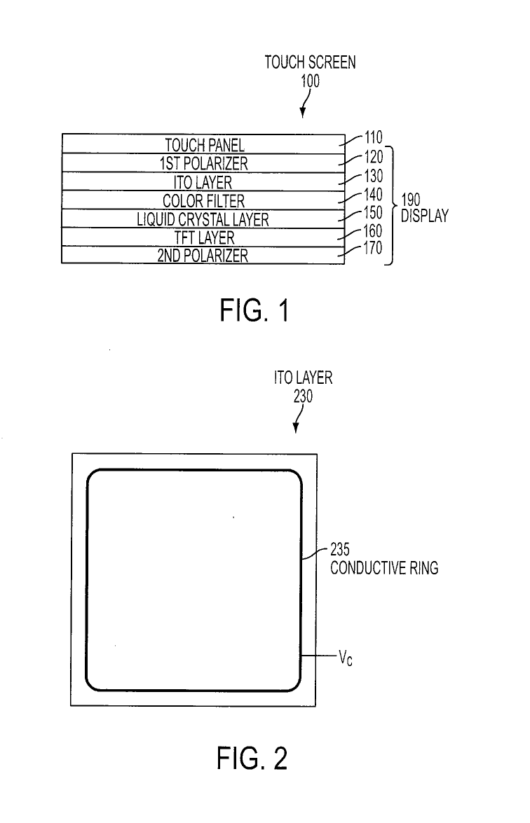

FIG. 1 illustrates an exemplary touch screen according to various embodiments. In the example of FIG. 1, touch screen 100 can include touch panel 110 to detect a proximate touch and display 190 to display graphics, images, and text. The display 190 can include polarizer 120 to polarize light transmitted through the display, conductive layer 130 to improve color displaying, color filter 140 to provide color displaying, liquid crystal layer 150 to provide liquid crystal display elements, thin film transistor (TFT) layer 160 to provide TFT circuitry to operate the display, and polarizer 170 to polarize the light transmitted through the display from an adjacent light source. In some embodiments, the conductive layer 130 can be an indium-tin-oxide (ITO) layer.

The conductive layer 130 can have one or more conductive elements coupled to or disposed along the periphery of the conductive layer. A conductive element can electrically contact the conductive layer 130 at multiple positions around the periphery and can drive the conductive layer from the multiple contact positions. The multiple contact positions can be continuous along the length of a conductive element, at discrete points along the length of the conductive element, or a combination thereof. In some embodiments, a conductive element can be a single continuous segment connected to a voltage source to drive the conductive layer 130. In other embodiments, a conductive element can have multiple discrete segments, each segment either individually or together connected to the voltage source to drive the conductive layer 130 either together or in sequence according to the needs of the touch screen. The sequence can include driving one or more segments in series or in parallel, or driving any number of segments in any patterned or random order according to the needs of the touch screen.

The touch panel 110 can be a self capacitance panel, including an array of pixels that can be formed at spatially separated electrodes, although it should be understood that other pixel configurations can be employed. In self capacitance embodiments, each pixel can have an associated capacitance formed between the electrode and ground, and when applicable, an associated capacitance formed between the electrode and an object, e.g., a user's finger or hand, proximate thereto. The electrodes can be coupled to conductive traces, where one set of conductive traces can form drive lines to drive the electrodes with drive signals from drive circuitry and another set of conductive traces can form sense lines to transmit touch or sense signals, indicative of a touch proximate to the panel 110, from the electrodes to sense circuitry.

To detect a touch proximate to the panel 110, in some embodiments, a capacitance change at an electrode caused by the formed capacitance between the proximate object and the electrode can be detected, along with the position of the electrode. This capacitance change can be transmitted to the sense circuitry for further processing to indicate the detected touch.

In an alternate embodiment, the touch panel 110 can be a mutual capacitance panel, including an array of pixels that can be formed at crossings of drive and sense lines. In mutual capacitance embodiments, each pixel can have an associated capacitance formed between the crossing drive and sense lines. The drive lines can be stimulated with stimulation signals from drive circuitry and the sense lines can transmit touch or sense signals to sense circuitry.

To detect a touch proximate to the panel 110, in some embodiments, a capacitance change at each pixel caused by an object, e.g., a user's finger or hand, proximate thereto shunting current from the electric field formed by the crossing drive and sense lines. The capacitance change can be transmitted to the sense circuitry for further processing to indicate the detected touch.

FIG. 2 illustrates an exemplary conductive layer having a conductive ring coupled thereto according to various embodiments. In the example of FIG. 2, conductive layer 230 can have conductive ring 235 coupled to or disposed around a perimeter of the conductive layer. The conductive ring 235 can be an opaque or otherwise non-transparent low resistance material, such as copper, silver, aluminum, lithium, and the like. The conductive ring 235 can be in the form of tape, ink, sputtered metal, and the like. The conductive layer 230 can be a transparent material, such as ITO and the like. The conductive ring 235 can be electrically coupled to voltage source Vc to drive a voltage through the conductive layer 230. This configuration of the conductive ring and the conductive layer can advantageously provide a grounding shield for limiting display interference and/or increased bandwidth for improved touch sensitivity, as will be described below.

In some embodiments, the conductive ring 235 can be a continuous ring. In other embodiments, the conductive ring 235 can be segmented into separate, adjacent portions, where the portions can be connected individually or together to the voltage source and can drive the conductive layer 230 together or in sequence.

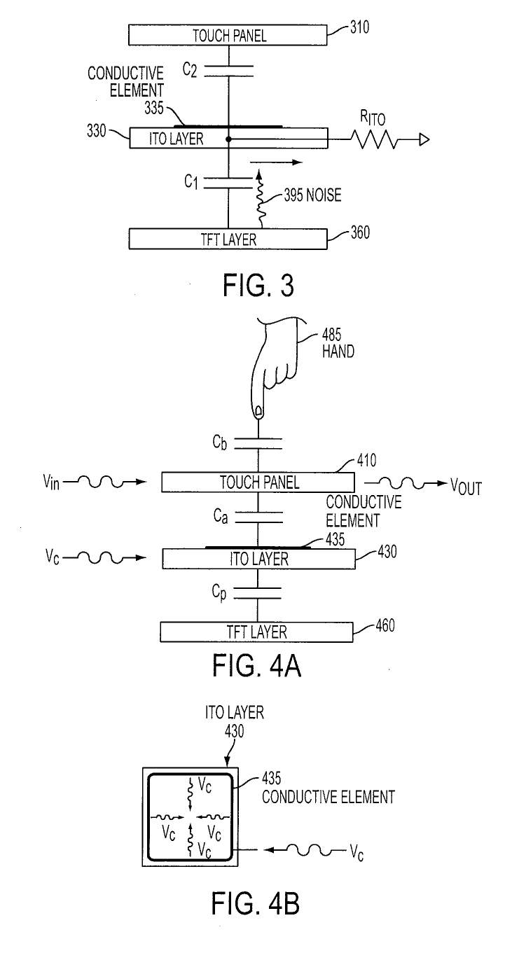

FIG. 3 illustrates an exemplary conductive layer acting as a grounding shield according to various embodiments. A touch screen display can generate noise that can interfere with the ability of an adjacent touch panel to detect a touch. The noise can come from the display TFT layer, in particular, and can interfere with the capacitance change detected by the touch panel. To limit the noise reaching the touch panel, a grounding shield can be placed between the TFT layer and the touch panel. In the example of FIG. 3, TFT layer 360 can generate noise 395. Conductive layer 330 having conductive element 335, e.g., the conductive ring of FIG. 2, can be disposed between the TFT layer 360 and touch panel 310 to act as a grounding shield. The TFT layer 360 can form capacitance C1 with the conductive layer 330 and the conductive layer can form capacitance C2 with the touch panel 310, with a total effective capacitance as the series capacitance of C1 and C2. If the conductive layer 330 is not attached to AC ground, the noise 395 can be transferred to the touch panel 310. If the conductive layer 330 is attached to AC ground, with ideally zero resistance, all the noise 395 can be shunted to ground and none of the noise can interfere with the touch panel 310. In reality, though, the conductive layer 330 can have some resistance R_{ITO} from its conductive material. However, the resistance R_{ITO} can be minimized by the conductive element 335 driving the conductive layer 330. As such, much of the noise 395 can be shunted to ground rather than transferred to the touch panel 310. Accordingly, the conductive layer 330 coupled to the conductive element 335 can act as an effective grounding shield in a touch screen.

In operation, the conductive element 335 can drive a voltage from multiple locations into the conductive layer 330. The conductive layer 330 can transmit the voltage through the layer to form a grounding shield with a minimized resistance R_{ITO}. The conductive layer can then shunt any display noise 395 to ground.

FIGS. 4a and 4b illustrate an exemplary conductive layer with increased bandwidth to improve touch sensitivity of an adjacent touch panel according to various embodiments. To improve the sensitivity of the touch screen's touch panel to detect a proximate touch, parasitic capacitance introduced by the adjacent touch screen display can be reduced or removed. To reduce or remove the display's parasitic capacitance from the touch measurement, a conductive layer can be placed between the display TFT layer and the touch panel and the conductive layer can modulate its voltage substantially similar to the voltage driving the touch panel. In the example of FIG. 4a, conductive layer 430 having conductive element 435, e.g., the conductive ring of FIG. 2, can be disposed between TFT layer 460 and touch panel 410. The TFT layer 460 can form parasitic capacitance Cp with the conductive layer 430 and the conductive layer can form capacitance Ca with the touch panel 410. An object, e.g., a user's hand 485, can be proximate to the touch panel 410 to form capacitance Cb, thereby generating a touch measurement Vout. The conductive layer 430 can remove or reduce the capacitances Cp and Ca from the touch measurement. To do so, the conductive element 435 can drive the conductive layer 430 with voltage Vc to modulate at substantially the same voltage as voltage Vin driving the touch panel 410. As a result, though there can be capacitance Ca between the conductive layer 430 and the touch panel 410, there can be no relative voltage change between the two, such that there can be no charge or current transferred to the touch panel. As such, the capacitances Ca and Cp can not become part of the touch measurement, and the touch measurement can include almost solely the capacitance change.

In some instances, the resistance of the conductive material in the conductive layer 430 and the capacitance Cp can impede the transmission of the voltage Vc through the conductive layer. This can delay the conductive layer 430 providing the voltage waveform substantially similar to that of the touch panel 410 and, hence, can diminish the sensitivity of the touch panel for detecting a proximate touch. The conductive element 435 according to various embodiments can reduce or eliminate this delay by driving the voltage Vc from multiple locations at the periphery of the conductive layer 430, thereby providing shorter distances and faster transmission of the voltage Vc, and increasing the bandwidth of the conductive layer. In the example of FIG. 4b, the conductive element 435 can drive the voltage Vc from multiple positions around the periphery of the conductive layer 430 toward the layer center. Accordingly, the conductive layer 430 coupled to the conductive element 435 can increase bandwidth to provide the highest frequencies possible to improve touch sensitivity of the touch panel 410.

In operation, the conductive element 435 can drive a voltage from multiple locations into the conductive layer 430, thereby increasing the bandwidth of the layer. The conductive layer 430 can transmit the voltage through the layer to modulate the voltage waveform substantially similar to the voltage waveform of the touch panel 410, quickly improving the panel's touch sensitivity.

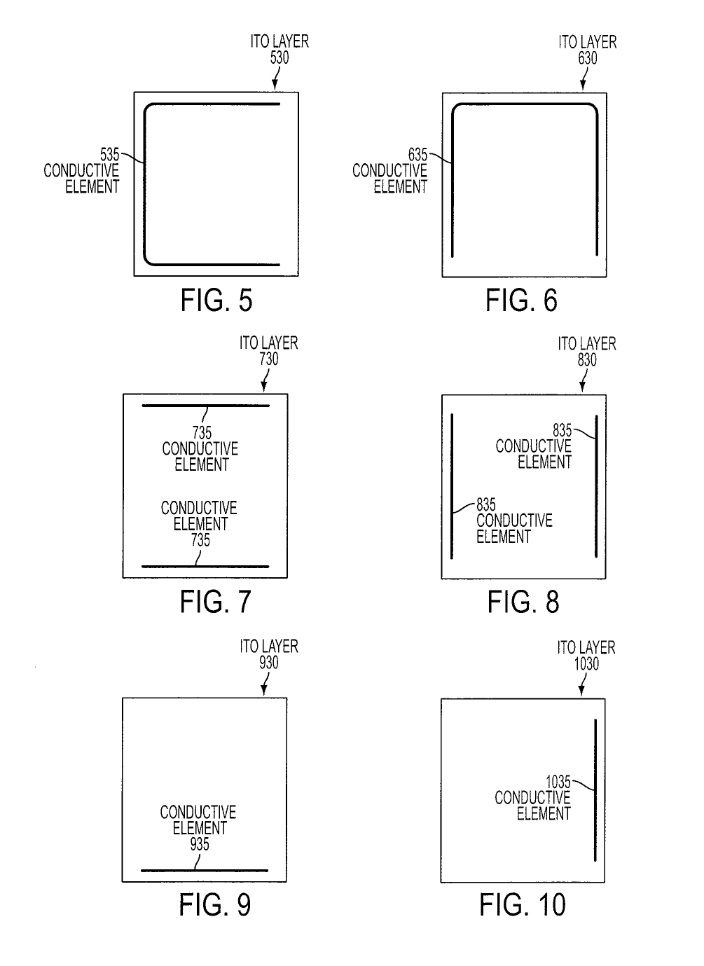

FIGS. 5 through 10 illustrate exemplary conductive layers having conductive elements coupled thereto according to various embodiments. In the example of FIG. 5, conductive layer 530 can have conductive element 535, a partial ring or an arc, coupled to or disposed at three sides around a periphery of the conductive layer. Here, the conductive element 535 can drive a voltage toward a center of the conductive layer 530. In this example, the rectangular-shaped conductive layer 530 has the conductive element 535 along all the sides except one of its longer sides. Similarly, in the example of FIG. 6, conductive layer 630 can have conductive element 635, a partial ring or an arch, coupled to or disposed at three sides around a periphery of the conductive layer. The conductive element 635 can drive a voltage toward a center of the conductive layer 630. In this example, the rectangular-shaped conductive layer 630 has the conductive element 635 along all the sides except one of its shorter sides.

In the example of FIG. 7, conductive layer 730 can have two conductive elements 735 coupled to or disposed at opposite sides of the periphery of the conductive layer. The conductive elements 735 can drive a voltage toward a center of the conductive layer 730. In this example, the rectangular-shaped conductive layer 730 has the conductive elements 735 along its shorter sides. Similarly, in the example of FIG. 8, conductive layer 830 can have two conductive elements 835 coupled to or disposed at opposite sides of the periphery of the conductive layer. In this example, the rectangular-shaped conductive layer 830 has the conductive elements 835 along its longer sides. The conductive elements 835 can drive a voltage toward a center of the conductive layer 830.

In the example of FIG. 9, conductive layer 930 can have one conductive element 935 coupled to or disposed at one side of the periphery of the conductive layer. The conductive element 935 can drive a voltage from the one side to the opposite side of the conductive layer 930. In this example, the rectangular-shaped conductive layer 930 has the conductive element 935 along either of its shorter sides. Similarly, in the example of FIG. 10, conductive layer 1030 can have one conductive element 1035 coupled to or disposed at one side of the periphery of the conductive layer. The conductive element 1035 can drive a voltage from the one side to the opposite side of the conductive layer 1030. In this example, the rectangular-shaped conductive layer 930 can have the conductive element 1035 along either of its longer sides.

Although the conductive layer is illustrated in the figures as having a rectangular shape, other shapes are also possible according to the needs of the touch screen. The positions and shapes of the conductive elements are not limited to those illustrated in the figures, but can include any others according to the needs of the touch screen. Any of the conductive elements and layers illustrated in the figures can be used with the touch screens illustrated in the figures. A conductive element can be a continuous element in electrical contact with a voltage source or can be segmented into separate, adjacent portions, where the portions can be electrically connected either individually or together to the voltage source and can drive the conductive layer together or in sequence.

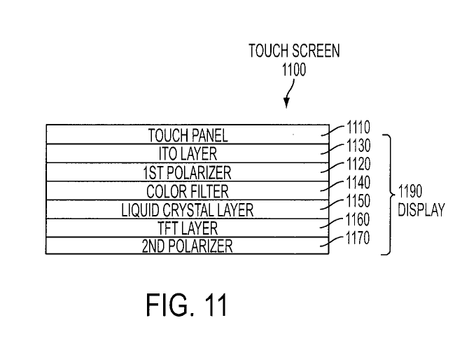

FIG. 11 illustrates another exemplary touch screen according to various embodiments. In the example of FIG. 11, touch screen 1100 can include touch panel 1110 and display 1190. The display 1190 can include conductive layer 1130, polarizer 1120, liquid crystal layer 1150, thin film transistor (TFT) layer 1160, and polarizer 1170. In some embodiments, the conductive layer 1130 can be an indium-tin-oxide (ITO) layer. In this example, the conductive layer 1130 having a conductive element can be disposed between the touch panel 1110 and the display polarizer 1120 (rather than between the polarizer and the color filter of FIG. 1). This can increase the distance between the TFT layer 1160 and the conductive layer 1130, thereby decreasing the capacitance between the two and the likelihood of the capacitance inadvertently affecting the touch panel 1110. Some larger touch screens can have this configuration.

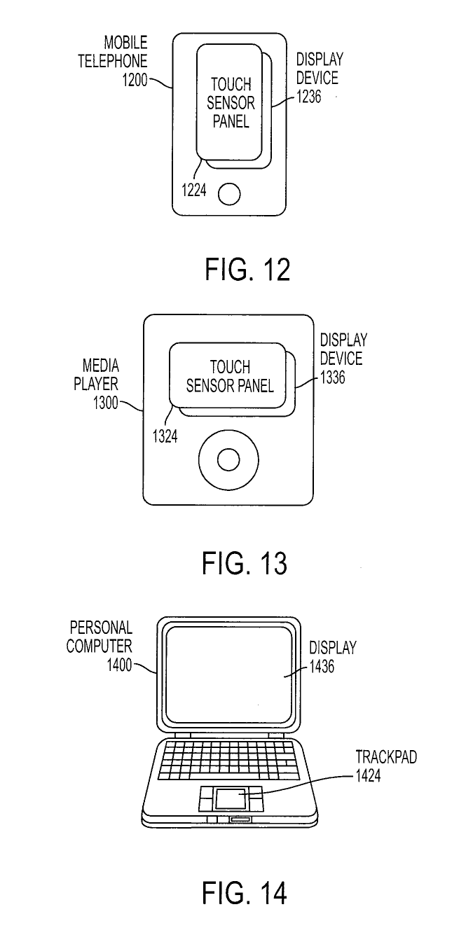

FIG. 12 illustrates an exemplary mobile telephone 1200 that can include touch sensor panel 1224, display 1236, and other computing system blocks for a touch screen according to various embodiments.

FIG. 13 illustrates an exemplary digital media player 1300 that can include touch sensor panel 1324, display 1336, and other computing system blocks for a touch screen according to various embodiments.

FIG. 14 illustrates an exemplary personal computer 1400 that can include touch sensor panel (trackpad) 1424, display 1436, and other computing system blocks for a touch screen according to various embodiments.

The mobile telephone, media player, and personal computer of FIGS. 12 through 14 can realize power savings, improved accuracy, faster speed, and more robustness by providing a touch screen according to various embodiments.

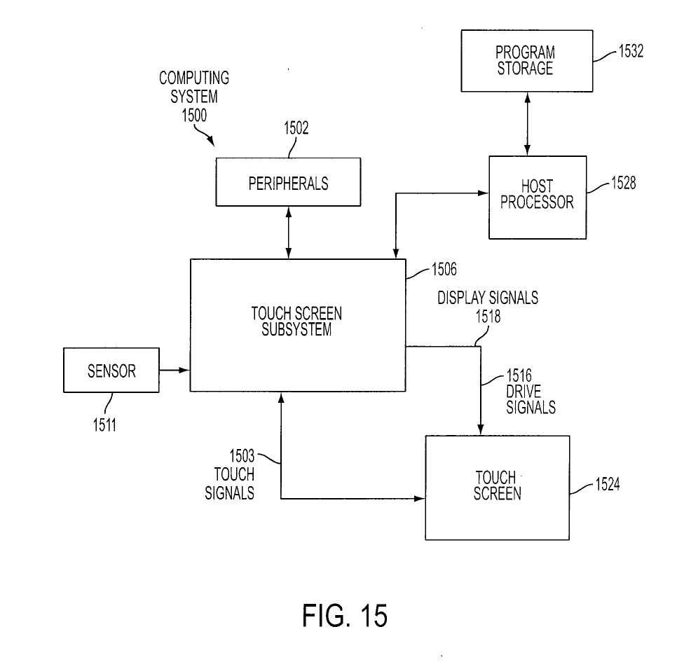

FIG. 15 illustrates an exemplary computing system 1500 that can incorporate a touch screen according to various embodiments described herein. In the example of FIG. 15, computing system 1500 can include touch screen 1524. The computing system can also include touch screen subsystem 1506, sensor 1511, one or more peripherals 1502, host processor 1528, and program storage 1532. The touch screen 1524 can include a touch panel having multiple electrodes for detecting a touch at the panel, where the electrodes can be driven by drive signals 1516, and for transmitting touch signals 1503 indicative of a detected touch to subsystem 1506. The touch screen 1524 can also include a display having a conductive element coupled to or disposed on a conductive layer according to various embodiments. The display can be driven with display signals 1518 to display graphics, text, images, and the like.

The touch screen subsystem 1506 can include various touch circuitry for driving the touch panel and processing the touch signals. For example, the subsystem 1506 can include circuitry to receive the touch signals and other signals from other sensors such as sensor 1511; generate and transmit the drive signals to the touch panel to drive the panel; access random access memory (RAM); and autonomously read from and control touch sensing channels.

The touch screen subsystem 1506 can also include various display circuitry for driving the display. For example, the subsystem 1506 can include circuitry to communicate with the host processor 1528 to receive data to be displayed; generate and transmit the display signals to the display to drive the display; and access RAM.

The peripherals 1502 can include, but are not limited to, RAM or other types of memory or storage, watchdog timers, and the like.

The host processor 1528 can receive outputs from the subsystems 1506 and perform actions based on the outputs that can include, but are not limited to, moving an object such as a cursor or pointer, scrolling or panning, adjusting control settings, opening a file or document, viewing a menu, making a selection, executing instructions, operating a peripheral device coupled to the host device, answering a telephone call, placing a telephone call, terminating a telephone call, changing the volume or audio settings, storing information related to telephone communications such as addresses, frequently dialed numbers, received calls, missed calls, logging onto a computer or a computer network, permitting authorized individuals access to restricted areas of the computer or computer network, loading a user profile associated with a user's preferred arrangement of the computer desktop, permitting access to web content, launching a particular program, encrypting or decoding a message, and/or the like. The host processor 1528 can also perform additional functions that may not be related to touch screen processing, and can be coupled to program storage 1532. In some embodiments, the host processor 1528 can be a separate component from the subsystem 1506, as shown. In other embodiments, the host processor 1528 can be included as part of the subsystem 1506. In still other embodiments, the functions of the host processor 1528 can be performed by the subsystem 1506 and/or distributed among other components of the subsystem.

One or more of the functions described above, can be performed, for example, by firmware stored in memory (e.g., one of the peripherals) and executed by the subsystem 1506, or stored in the program storage 1532 and executed by the host processor 1528. The firmware can also be stored and/or transported within any computer readable storage medium for use by or in connection with an instruction execution system, apparatus, or device, such as a computer-based system, processor-containing system, or other system that can fetch the instructions from the instruction execution system, apparatus, or device and execute the instructions. In the context of this document, a “computer readable storage medium” can be any medium that can contain or store the program for use by or in connection with the instruction execution system, apparatus, or device. The computer readable storage medium can include, but is not limited to, an electronic, magnetic, optical, electromagnetic, infrared, or semiconductor system, apparatus or device, a portable computer diskette (magnetic), a random access memory (RAM) (magnetic), a read-only memory (ROM) (magnetic), an erasable programmable read-only memory (EPROM) (magnetic), a portable optical disc such a CD, CD-R, CD-RW, DVD, DVD-R, or DVD-RW, or flash memory such as compact flash cards, secured digital cards, USB memory devices, memory sticks, and the like.

The firmware can also be propagated within any transport medium for use by or in connection with an instruction execution system, apparatus, or device, such as a computer-based system, processor-containing system, or other system that can fetch the instructions from the instruction execution system, apparatus, or device and execute the instructions. In the context of this document, a “transport medium” can be any medium that can communicate, propagate or transport the program for use by or in connection with the instruction execution system, apparatus, or device. The transport medium can include, but is not limited to, an electronic, magnetic, optical, electromagnetic or infrared wired or wireless propagation medium.

It is to be understood that the computing system is not limited to the components and configuration of FIG. 15, but can include other and/or additional components in multiple configurations according to various embodiments.

Although embodiments have been fully described with reference to the accompanying drawings, it is to be noted that various changes and modifications will become apparent to those skilled in the art. Such changes and modifications are to be understood as being included within the scope of the various embodiments as defined by the appended claims.

What is claimed is:

1. A device comprising:
a conductive layer configured to form a shield; and
a conductive element disposed along at least one side at a periphery of the conductive layer to electrically contact the conductive layer at multiple positions at the periphery and configured to drive the formation of the shield from the multiple positions.

2. The device of claim 1, wherein the conductive element is disposed in a ring around the perimeter of the conductive layer.

3. The device of claim 1, wherein the conductive element is disposed along three sides of the conductive layer.

4. The device of claim 1, wherein the conductive element is disposed along opposite sides of the conductive layer.

5. The device of claim 1, wherein the conductive element is disposed along one side of the conductive layer.

6. The device of claim 1, wherein the conductive element is configured to drive a voltage into the conductive layer to form the shield.

7. The device of claim 1, wherein the conductive layer comprises a transparent conductor.

8. The device of claim 1, wherein the conductive element comprises a non-transparent conductor.

9. A touch screen comprising:
a touch panel configured to detect a touch proximate thereto; and
a display adjacent to the touch panel, the display including a conductive layer and a conductive element disposed along at least one side at the periphery of the conductive layer to electrically contact the conductive layer at multiple positions at the periphery, the conductive element driving the conductive layer to limit display noise interfering with the touch panel detecting the touch.

10. The touch screen of claim 9, wherein the display includes a first polarizer adjacent to the touch panel, the conductive layer having the conductive element disposed thereon adjacent to the first polarizer, a color filter adjacent to the conductive layer, a liquid crystal layer adjacent to the color filter, a thin film transistor layer adjacent to the liquid crystal layer, and a second polarizer adjacent to the thin film transistor layer.

11. The touch screen of claim 10, wherein the conductive layer shields the touch panel from noise of at least the thin film transistor layer.

12. The touch screen of claim 9, wherein the display includes the conductive layer having the conductive element disposed thereon adjacent to the touch panel, a first polarizer adjacent to the conductive layer, a color filter adjacent to the first polarizer, a liquid crystal layer adjacent to the color filter, a thin film transistor layer adjacent to the liquid crystal layer, and a second polarizer adjacent to the thin film transistor layer.

13. A method comprising:
driving a voltage through a conductive element disposed along a periphery of a conductive layer;
transmitting the voltage through the conductive layer from multiple positions along the conductive element; and
forming the conductive layer into a grounding shield via the transmitted voltage.

14. The method of claim 13, wherein driving a voltage comprises driving a voltage around a perimeter of the conductive layer.

15. The method of claim 13, wherein driving a voltage comprises driving the voltage along at least one side of the conductive layer.

16. The method of claim 13, wherein forming the conductive layer comprises forming the conductive layer to shunt noise to ground.

17. A method comprising:
driving a voltage through a conductive element disposed along at least one side at a periphery of a conductive layer to electrically contact the conductive layer at multiple positions at the periphery;
transmitting the voltage through the conductive layer; and
modulating the voltage in the conductive layer substantially as another voltage in an adjacent touch sensing device.

18. The method of claim 17, wherein transmitting the voltage comprises transmitting the voltage toward a center of the conductive layer from a ring around the perimeter of the conductive layer.

19. The method of claim 17, wherein transmitting the voltage comprises transmitting the voltage toward a center of the conductive layer from at least two sides of the conductive layer.

20. The method of claim 17, wherein transmitting the voltage comprises transmitting the voltage from one side of the conductive layer to an opposite side.

21. The method of claim 17, wherein modulating the voltage comprises substantially matching voltage waveforms between the conductive layer and the touch sensing device to adjust sensitivity of the touch sensing device.

22. A touch screen comprising:
a touch panel including electrodes configured to modulate a first voltage waveform; and
a display including a conductive layer configured to modulate a second voltage waveform and a conductive element disposed along a periphery of the conductive layer to drive the conductive layer from multiple positions along the conductive element,
wherein the first and second voltage waveforms are substantially the same.

23. The touch screen of claim 22, wherein the electrodes are self capacitive.

24. The touch screen of claim 22, wherein the conductive element comprises multiple segments configured to drive the conductive layer together or in sequence.

25. The touch screen of claim 22 incorporated into at least one of a mobile telephone, a personal computer, or a digital media player.
